(19) United States
(12) Patent Application Publication
(10) Pub. No.: US 2022/0085570 A1
(43) Pub. Date: Mar. 17, 2022

(54) NEURAL NETWORK CORRECTION FOR LASER CURRENT DRIVER

(71) Applicant: Julia Isaac, Los Altos, CA (US)

(72) Inventor: Julia Isaac, Los Altos, CA (US)

(21) Appl. No.: 17/109,107

(22) Filed: Dec. 1, 2020

Related U.S. Application Data
(60) Provisional application No. 63/079,373, filed on Sep. 16, 2020.

(51) Int. Cl. H01S 5/042; H01S 5/026

(52) U.S. Cl. CPC H01S 5/042; G06N 3/08; H01S 5/0261

(57) ABSTRACT

A correction system that compensates for the errors of the laser current driver such that a programmable laser current source will output actual currents closer to the desired currents.

### BACKGROUND

### FIELD OF THE INVENTION

This technology relates to the general field of machine learning, and has certain specific applications in controlling the current of a laser.

### DESCRIPTION OF THE RELATED ART

Neural networks are composed of an abundance of neurons, interconnected by synapses in a unique way. Typically, the networks encompass input neurons that receive information from outside the network (given by the user), output neurons that export signals to, and at least one hidden layer of neurons that receive and pass along information to other neurons. An advantage of neural networks is that they can work with imperfect input data. Thus, neural nets are able to take any set of inputs and propagate through them to generate weights. In a problem with a complicated function and thus implementation, such as those presented here, neural networks are able to train with much greater accuracy than other contemporary solutions.

### SUMMARY

The present invention comprises a laser current driver generally consisting of input current and a laser diode. The general problem is the current being distorted from what the user desires to an achieved current value after the system. In one embodiment of the present invention, a neural network is configured separately from the electronics (programmed and run on a computer). In other embodiments, the neural network may be configured directly into the electronic environment as hardware.

### BRIEF DESCRIPTION OF THE DRAWINGS

It is stressed that the various embodiments depicted in the accompanying drawings are solely for illustrative purposes, and do not limit the scope of the inventions. Further facets and other advantages will become clear to those of ordinary skill in the art from the following description made with reference to the drawings:

FIG. 1 is a simplified diagram of the laser current source environment.

FIG. 2 is a block diagram demonstrating the neural network correcting the laser source.

FIG. 3 is a modified diagram of FIG. 2 except with the optional mapping and unmapping before and after the neural network respectively.

FIG. 4 is a simplified diagram of a typical neural network utilized by the laser current driver.

FIG. 5 is a flowchart of the overall logic behind the neural network training process.

### DETAILED DESCRIPTION OF THE INVENTION

The terminology used herein is for the purpose of describing particular embodiments only and is not intended to be limiting of the invention. Unless otherwise defined, all terms used herein have the same meaning as commonly understood by one having ordinary skill in the art to which this invention belongs. Thus, all terms used or undefined as such should be interpreted as having a meaning that is consistent with their meaning in the context of the relevant art and the present disclosure and will not be interpreted in an idealized or overly formal sense unless expressly so defined herein.

In describing the invention, it must be declared that all steps disclosed have unique individual benefits, and may be modified or even unused for another's intention, since for clarity not every possible combination of the technology will be covered. Nevertheless, the specification and claims should be read with the understanding that such combinations are entirely within the scope of the invention and the claims.

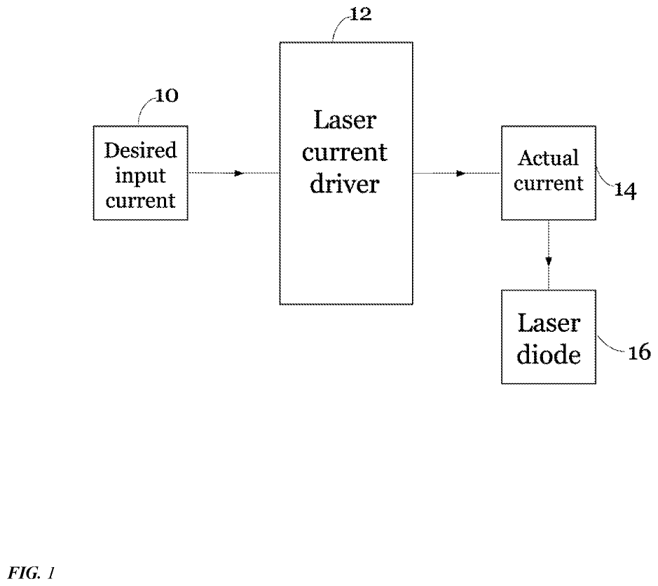

The present invention will now be described via appended figures representing preferred embodiments. FIG. 1 depicts the preferred environment of the invention. As shown, 10 represents the desired input current. 12 is a laser current driver, which may distort the current desired to produce the actual current 14. The laser diode 16 itself may vary completely in different embodiments.

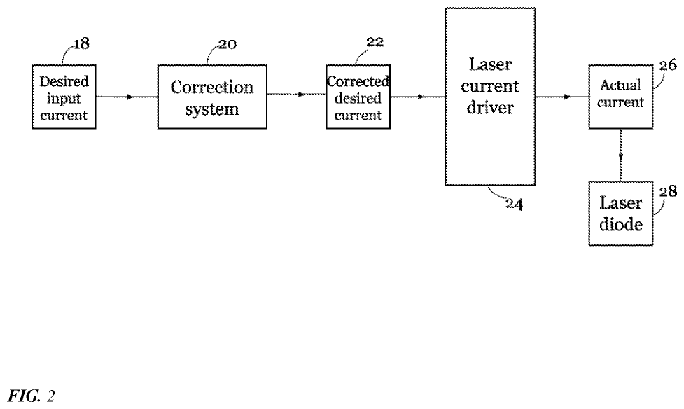

FIG. 2, which is a modified version of FIG. 1, borrows its environment and adds in the neural network correction system 20, which takes the desired input current 18 and amends it to the corrected desired current 22. The rest of the figure is precisely identical to the set up of FIG. 1—the preferred embodiment simply attaches the correction system as an intermediate. Again, it is stressed that the correction system may be either incorporated in software or directly in hardware, depending upon the user's preference, and that both of these embodiments are in the scope of this patent.

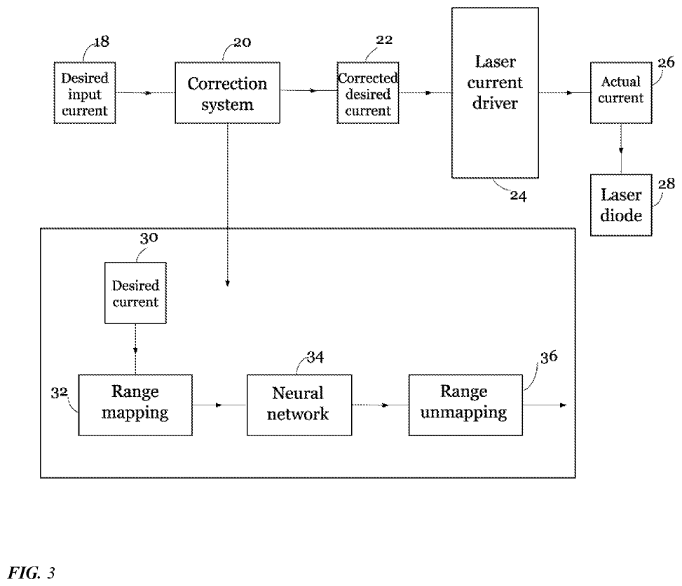

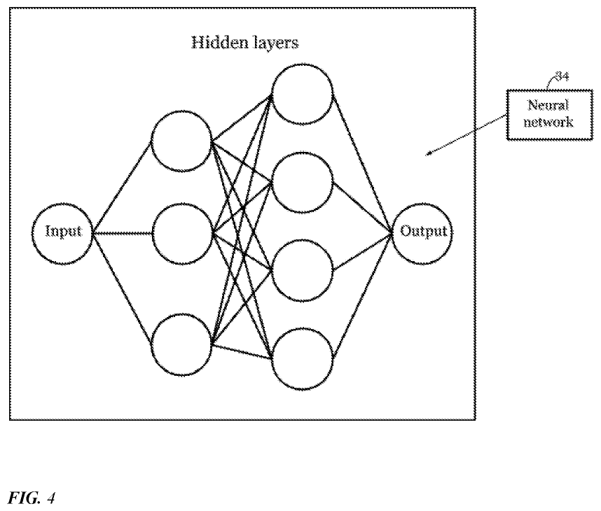

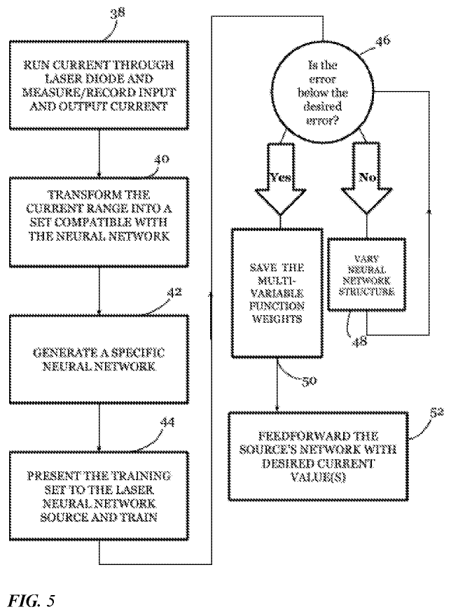

After obtaining a setup (not limited to the specific one illustrated in FIG. 1/2), FIG. 5 provides a basic flowchart that should dictate the actual data collection, implementation, training, and more. For as many trials as possible, the user should decide on various current (as expressed in Amperes) inputs to run through the laser system and record as many inputs and outputs as desired 38 (more data points generally result in higher accuracy when training). Note that due to some disturbance (eg. design and manufacturing imperfections, parasitic properties, and various nonlinear phenomena), the input (which is the desired output) currents of the system should be somewhat divergent and that this invention serves to solve this discrete problem. The neural network design typically has a limited range of outputs, depending upon the activation (eg. sigmoid) function. This may include, for example, 0 to 1, −1 to 1, or −½ to ½ . Thus, the neural network driver (not limited to any specific type of device/embodiment) may only produce outputs from the numerical values 0 to 1, therefore it is conducive for the user to transform its data 40 from a raw set to a final data set between these two values to map from the physical range of actual currents to the mathematical range that the neural network can work with. The amount to which a user should scale the data depends upon the diverse currents to which the system will be subjected to. The inventor recommends this to be a linear transformation but does not limit the extent of the patent to only this method. Other non-linear methods are applicable, as long as the user can apply the inverse function to achieve values typical of the input current. This way, the values can alternate between real currents and the numerical range that the neural network can work efficiently. Examining FIG. 3, the desired current 30 will be processed through a range mapping 32, fed to the neural network (which will be discussed later in more detail) 34, the network's outputs should be processed again by a range unmapping 36. Referring back to FIG. 5, the user should generate a specific neural network by which the modified data set will be run 42. FIG. 4 shows one example of what this general neural network could look like visually, given an input and producing an output. This step will be left up to the user's preference in terms of the actual layer or neuron structure of the network, though one embodiment of this starting structure could include 3 layers and randomly generated weights between −1×10⁴ to 1×10⁴. The neural network source should then be trained 44 with these preferences. The error this invention achieves is not fixed and varies between different systems yet is generally multitudes better than a linear interpolation model, which is the current state of the art. It is because of the neural network's inherent nonlinearity that it is capable of outperforming the linear least-squares fit. The network should continue training until it reaches a desired error 46 or the error reaches the minimum possible for that specific layer and neuron structure. If the latter possibility occurs, the structure of the neural network shall be varied 48 until the former is reached. The network's weights are then saved 50.

In the final step, the system, consisting of the laser current source and correction network, should be properly calibrated. The user may now input a desired current to the system. It should therein feed the compensated desired current value to the current source (or what current the user should input into the laser system) and the laser should experience a current extremely close to the desired one and feedforward the network 52.

What is claimed is:

1. A laser current driver comprising a programmable current source with a neural network correction system.

2. A system as in claim 1 with range mapping before and after the neural network.
